(19) United States
(12) Patent Application Publication
(10) Pub. No.: US 2004/0185661 A1
(43) Pub. Date: Sep. 23, 2004

(54) Scrubber system for pretreatment of an effluent waste stream containing arsenic

(76) Inventor: John Michael Sherer, Gilbert, AZ (US)

Correspondence Address: ADVANCED TECHNOLOGY MATERIALS, INC., 7 Commerce Drive, Danbury, CT, 06810, US

(21) Appl. No.: 10/390,475

(22) Filed: Mar. 17, 2003

(51) Int. Cl. H01L 21/302; H01L 21/461

(52) U.S. Cl. 438/689

(57) ABSTRACT

A point of use scrubber system for pre-treating an effluent waste stream comprising an arsenic component, deriving from a compound semiconductor etch process tool. The system uses a scrubber comprising a sorbent bed, which contacts the arsenic component and retains thereon the arsenic component through a chemisorption or physisorption reaction. The scrubber is located in the exhaust line of the etch process tool's exhaust pump, upstream of a main abatement system.

### BACKGROUND

Embodiments described herein relate to the removal of arsenic containing component from an effluent waste stream of a semiconductor process. In particular, embodiments relate to the removal of an arsenic containing component from an effluent waste stream deriving from a semiconductor etch process.

### BACKGROUND OF THE RELATED ART

Compound Semiconductors, such as gallium arsenide (GaAs), gallium arsenide phosphide (GaAsP), indium phosphide (InP), gallium aluminum arsenic (GaAlAs), and indium gallium phosphide (InGaP) are candidates to replace current silicon technology.

These compounds, particularly GaAs have better semiconducting properties for certain operations over silicon and are consequently being used to create low inductance electrical interconnects for high power heterojunction bi-polar transistors (HBTs), monolithic microwave integrated circuits (MMICs) and low inductance grounds for field effect transistors (FETs) for technologies such as wireless and optical communications.

Processing of compound semiconductor materials involves a multitude of steps and technologies, during which decontamination activities and wastewater treatment are required to contain, remove and/or destroy toxic and/or hazardous components deriving from the processing step. Of particular concern are MOCVD, MBE, and dry etch processes where arsenic containing components are introduced to process waste streams. For example, MOCVD processes use arsine and MBE processes use arsenic to grow thin epitaxial layers on GaAs substrates.

At the completion of a photoresist develop step a mask pattern is defined in the photoresist layer and is ready for etch. In an etch step an image is permanently transferred into the surface layer on the wafer. Etching is the process of removing the top layer from the wafer surface through the openings in the resist pattern.

Dry etching is the exposure of a substrate surface to etchant vapors. Halogenated compounds such as BCl₃, F₂, Cl₂, and perfluorocarbons are most common. Such a process provides a continuous replenishment of the etchant vapor at the substrate surface with fresh vapors and instant etch termination. The etchant vapor attacks the substrate surface converting it into volatile components, which are removed and exhausted by a vacuum system to a downstream scrubber.

Dry etch processes pattern through wafer via holes directly into the GaAs substrate. The via etch is a large industrial hygiene concern since arsenic is present in the etch chamber as a by-product.

Arsenic chloride (AsCl₃) and its derivatives are a major by-product in gallium arsenide etch systems. AsCl₃, readily reacts with water and/or air to form arsenic containing particulates that condense and deposit in a post pump, pre-abatement exhaust line, clogging the exhaust line and disrupting process.

The arsenic containing condensables may be further compounded by solid boric oxide and boric acid, which readily form by the reaction of BCl₃ etchant gases with water vapor and oxygen.

The process line downstream of the etch tool and scrubber/abatement system may therefore require frequent maintenance to keep the pump line, exhaust line and scrubber entrance clear of condensed byproducts.

Maintenance activities present the greatest hazard risks and the largest exposure potential to semiconductor fabs, thereby adding to the overhead cost associated with the manufacturing of related devices. Cleaning of process lines containing arsenic requires respiratory equipment and PPE. An opening in the process line will liberate chlorinated, fluorinated and arsenic containing compounds.

Accordingly, there is a need in the art to provide a point of use scrubber to control the hazard risk of arsenic exposure in a semiconductor fab.

In the case where the downstream scrubber is a wet abatement system, arsenic-containing components, which pass through the process line without reacting prematurely with air or water, contaminate the wet bed waste stream. As treatment of arsenic containing wastewater is of major environmental concern, further treatment is required to extract the arsenic-containing component out of the waste stream resulting in increased expense and operating costs.

Moreover, air pollution regulations, employee health concerns and growing awareness of toxic agents from manufacturing demand increased improvements in process exhaust gas conditioning.

There is a need in the art, to provide a point of use scrubber system capable of reducing the hazards associated with arsine containing effluent waste streams as well as precipitates originating therefrom.

Accordingly, it is one objective of the instant invention, to provide a point of use scrubber to control the hazard risk of arsenic exposure in a semiconductor fab.

It is a further objective of the instant invention, to provide a point of use scrubber system to control the hazard risk of arsenic exposure deriving from an etch process in a semiconductor fab.

It is a still further objective of the instant invention, to provide a point of use pretreatment scrubber to control the premature precipitation of arsenic containing components deriving from a compound semiconductor etch process.

### SUMMARY OF THE INVENTION

The present invention relates generally to an abatement apparatus and system for the pretreatment of an effluent waste stream deriving from a semiconductor process tool.

In one aspect, the invention relates to an abatement apparatus, comprising sorbent-based scrubber, which when joined in fluid flow communication with an effluent gas stream comprising a hazardous component, reduces the concentration of the hazardous component in the effluent gas stream.

In one aspect, the instant invention relates to a point of use scrubber for pre-treating an effluent waste stream comprising an arsenic component, said waste stream deriving from an upstream process pump of a compound semiconductor etch process, said scrubber comprising a canister having:

an inlet in gas flow communication with an upstream process exhaust pump;

an outlet in gas flow communication with a downstream, main abatement system; and

a sorbent bed;

wherein said sorbent bed contacts the effluent waste stream comprising the arsenic containing component ahead of the downstream main abatement system to effectively reduce the concentration of toxic arsenic component from the hazardous waste stream.

In one aspect the instant invention, relates to a point of use, scrubber for pre-treating an effluent waste stream comprising an arsenic component, said waste stream deriving from an upstream process pump of a compound semiconductor etch process, said scrubber comprising:

an up-flow canister comprising:

a lower section plenum space;

an upper section plenum space;

at least one dry resin sorbent bed layer therebetween

an inlet in gas flow communication with the upstream process pump; and

an outlet in gas flow communication with a downstream main scrubber system,

arranged such that process effluent waste stream flows in an upward direction to effectively reduce the concentration of toxic arsenic component from the hazardous waste stream.

In a further aspect the present invention, relates to a process for reducing the concentration of arsenic containing component in an effluent waste stream deriving from an upstream process pump of a compound semiconductor etch process tool, said process comprising:

contacting the arsenic-containing component in the effluent waste stream with a dry resin sorbent material to effectively chemisorb or physisorb thereon at least a portion of the arsenic component,

wherein the scrubber system is coupled to the exhaust line of the process pump, upstream of a main abatement system.

In a still further aspect the instant invention, relates to a point of use scrubber system for pre-treating an effluent waste stream comprising an arsenic component, said waste stream deriving from an upstream process pump of a compound semiconductor etch process tool, said pre-treat scrubber system comprising:

a compound semiconductor etch chamber for etch processing of a gallium arsenide substrate;

a process pump downstream of and coupled to said etch chamber for removing the effluent waste stream comprising arsenic component from said etch chamber;

a main abatement system downstream of said process pump for receiving and treating of the effluent waste stream comprising arsenic component; and

a scrubber comprising a sorbent bed, located downstream of the process pump and upstream of said main abatement system, and in fluid flow communication with the arsenic containing effluent waste stream, such that the effluent waste stream contacts said sorbent bed prior to entry into said main abatement system, to reduce therein, the concentration of arsenic containing component in the effluent waste stream.

In a still further aspect, the present invention relates to a process for the point of use scrubbing of an arsenic containing component in an effluent waste stream deriving from a compound semiconductor etch process tool, said process comprising:

contacting a gallium arsenide substrate disposed in an etch chamber, with a halogenated etching gas to produce a volatile etch by-product comprising arsenic;

withdrawing the effluent waste stream comprising the volatile etch by-product from the etch chamber, using a vacuum exhaust pump downstream of the etch chamber;

contacting the volatile etch by-product comprising arsenic with a dry resin sorbent material to effectively chemisorb or physisorb thereon at least a portion of the arsenic of the volatile etch by-product, thereby producing an effluent waste stream having a reduced concentration of arsenic; and

withdrawing from the dry resin sorbent material an effluent waste stream having a reduced concentration of arsenic for disposition to a main abatement system.

### BRIEF DESCRIPTION OF THE DRAWINGS

FIG. 1 shows a typical compound semiconductor process useful for etching a surface layer of a compound semiconductor substrate such as GaAs.

FIG. 2 shows a compound semiconductor process employing a point of use scrubber system for pre-treating an effluent waste stream according to one embodiment of the present invention.

FIG. 3 shows a more detailed version of the pretreatment scrubber according to a further embodiment of the invention.

### DETAILED DESCRIPTION OF THE INVENTION AND PREFERRED EMBODIMENTS THEREOF

The present invention provides an abatement system and process for removing an arsenic containing component from an effluent waste stream, which is preferably derived from a semiconductor process tool.

The system comprises a point of use scrubber in a process line of a semiconductor etch process tool, where an arsenic containing component is contacted by a sorbent material to chemisorb and/or physisorb thereon, the arsenic containing component. Preferably, the arsenic-containing component is produced during an etching step of a compound semiconductor process by the reaction of an etching gas with a compound semiconductor substrate.

The present invention accommodates the collection of toxic arsenic containing gas components deriving from an exhaust pump of a compound semiconductor etch chamber that if allowed to pass to a downstream abatement system, would prematurely react with oxygen and/or water introduced into the effluent waste stream line, by the downstream abatement system and/or a house exhaust system.

As used herein, the scrubber for pre-treatment of an effluent waste stream containing an arsenic component, is intended to be broadly construed, and may alternatively comprise, consist, or consist essentially of the specific stated components hereafter specifically identified. Although exemplary embodiments describe particular aspects, any changes, modifications, and substitutions may be made without departing from the spirit and scope of these embodiments.

The abatement system comprises a scrubber upstream of a main abatement system and downstream of an exhaust pump of a semiconductor etch process tool. Preferably the process tool etches a wafer having deposited thereon an arsenic containing film. More preferably the tool is used in a process for etching a compound semiconductor wafer having a substrate comprising arsenic including but not limited to gallium arsenide (GaAs), gallium arsenide phosphide (GaAsP), and gallium aluminum arsenide (GaAlAs).

At the completion of a photoresist develop step a mask pattern is defined in the photoresist layer and is ready for etch. In an etch step an image is permanently transferred into the surface layer of the substrate. Etching is the process of removing the top layer from the substrate surface through openings in the resist pattern. Vapor etching technology is the exposure of the wafer to etchant vapors. Such a process provides a continuous replenishment of the etchant gas at the surface with fresh vapors and instant etch termination. Halogenated gases including but not limited to BCl₃, F₂, Cl₂, HBr, SCl₄, HCl, SF₆ and PFC gases are used as etching gases.

In an etching chamber of an etch process tool, the halogenated etchant gases react with a component on the substrate surface to form a volatile species that is removed from the surface of the wafer and out of the etch chamber by the tool's exhaust pump. The volatile species therefore is swept away in the etch tool's effluent waste stream by an exhaust pump downstream of the etching chamber.

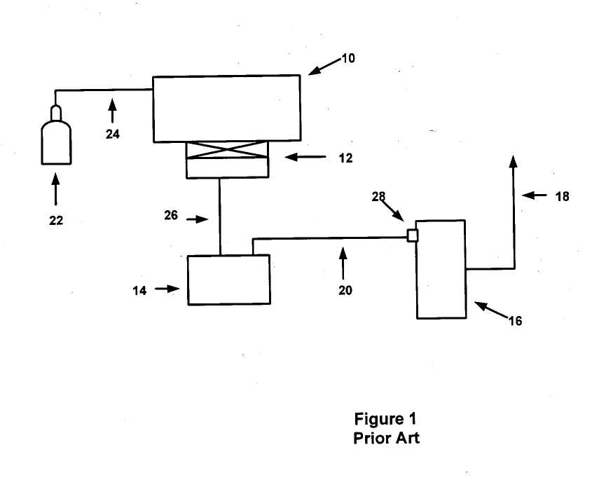

FIG. 1 shows a typical “Prior Art” compound semiconductor process useful for etching a surface layer of a compound semiconductor substrate such as GaAs. Etching gas, such as Cl₂ flows from gas source cylinder 22, through process line 24 to etching chamber 10 employing high vacuum turbo pump 12. A wafer comprising a GaAs substrate surface (not shown), resides in the etching chamber. The substrate surface contacts Cl₂ etching gas and reacts therewith to form volatile GaCl₃ and AsCl₃. The GaCl₃ and AsCl₃ and unreacted etchant gas, Cl₂, are withdrawn from the surface of the wafer and out of the etch chamber in process exhaust line 26, by high vacuum turbo pump 12 and the tool's exhaust pump 14. Exhaust pump 14 coupled to effluent waste stream line 20 the length of which may be up to 30 feet, exhausts effluent waste stream comprising the GaCl₃ and AsCl₃ and unreacted etchant gas for decontamination treatment to wet scrubber 16. However, back streaming from wet scrubber 16 in effluent waste stream line 20 are water and/or air, which react with the AsCl₃ component in the effluent waste stream to form solid arsenic oxides, which deposit in and clog effluent waste stream line 20 and wet scrubber entry 28. Arsenic oxides are equally as toxic as arsenic.

Moreover, AsCl₃ component disposed to wet scrubber unit 16 for decontamination removal, passes through the water scrubber unabated and therefore is exhausted to the house exhaust in line 18 where it sees air and reacts therewith to form solid particulates of arsenic oxides, which deposit in the exhaust line 18 and duct work of the house exhaust system (not shown). There is therefore, a potential, for toxic arsenic oxides to enter the environment or depending on environmental conditions, for particulates of the arsenic oxides to become entrained in an air up-take system.

Arsine is not water soluble, making water scrubbers ineffective without the addition of dangerous chemicals. Even with chemical injection, the effluent water will become contaminated with arsenic, which is a very closely regulated water pollutant. Thermal abatement methods including combustion and oxidation of arsine generate arsenic oxides, which will also deposit in the exhaust line 18 and duct-work of the house exhaust system.

The present invention reduces the concentration of arsenic component in an effluent waste stream before the arsenic component can come into contact with water and/or air, by coupling a point of use scrubber downstream from, yet in close proximity to, the process exhaust pump.

The present invention obviates the premature precipitation reaction occurring between an arsenic containing species and water and/or air by locating a point of use scrubber downstream of the process exhaust pump and upstream of the main abatement unit. The point of use scrubber comprises a sorbent bed, which contacts and reacts with the volatile arsenic-containing species before the volatile arsenic containing species contacts the water and/or air introduced in the downstream process line by the main abatement system. The sorbent bed may be fixed or fluidized. Preferably the sorbent bed comprises a dry resin sorbent material, which works to physically adsorb or irreversibly chemisorb thereon, the arsenic-containing component.

Accordingly, the instant invention relates to a point of use scrubber for pre-treating an effluent waste stream comprising an arsenic component, said waste stream deriving from an upstream process pump of a compound semiconductor etch process, said scrubber comprising a canister having:

an inlet in gas flow communication with an upstream process exhaust pump;

an outlet in gas flow communication with a downstream, main abatement system; and

a sorbent bed;

wherein said sorbent bed contacts the effluent waste stream comprising the arsenic containing component ahead of the downstream main abatement system to effectively reduce the concentration of toxic arsenic component from the hazardous waste stream.

The canister useful for removing an arsenic component from an effluent waste stream of a compound semiconductor etch process provides for flow of the arsenic containing effluent waste stream into the canister and through the sorbent bed in either an upward or a downward direction, in a vertically upstanding canister.

More particularly, in one embodiment, the present invention relates to a point of use, scrubber for pre-treating an effluent waste stream comprising an arsenic component, said waste stream deriving from an upstream process pump of a compound semiconductor etch process, said scrubber comprising:

an up-flow canister comprising:

a lower section plenum space;

an upper section plenum space;

at least one dry resin sorbent bed layer therebetween

an inlet in gas flow communication with the upstream process pump; and

an outlet in gas flow communication with a downstream main scrubber system,

arranged such that process effluent waste stream flows in an upward direction to effectively reduce the concentration of toxic arsenic component from the hazardous waste stream.

And in a further embodiment, the present invention relates to a process for the point of use scrubbing of an arsenic containing component in an effluent waste stream deriving a compound semiconductor etch process tool, said process comprising:

contacting a gallium arsenide substrate disposed in an etch chamber, with a halogenated etching gas to produce a volatile etch by-product comprising arsenic;

withdrawing the effluent waste stream comprising the volatile etch by-product from the etch chamber, using a vacuum exhaust pump downstream of the etch chamber;

contacting the volatile etch by-product comprising arsenic with a dry resin sorbent material to effectively chemisorb or physisorb thereon at least a portion of the arsenic of the volatile etch by-product, thereby producing an effluent waste stream having a reduced concentration of arsenic; and

withdrawing from the dry resin sorbent material an effluent waste stream having a reduced concentration of arsenic for disposition to a main abatement system.

The up-flow canister as used herein is more fully described in co-pending, commonly assigned, U.S. patent application Ser. No. 10/370,159 having a filing date of Feb. 19, 2003, for Low Pressure Drop Canister for Fixed Bed Scrubber Applications and Method of Using Same, in the names of Paul J. Marganski, Theodore A. Shreve, Joseph Sweeney, Jose Arno, Mark Holst, and Karl Olander, and is incorporated herein by reference in its entirety.

The point of use scrubber accommodates the collection of hazardous gases, typically considered pollutants, in an effluent gas stream by contacting the effluent gas stream with a sorbent material, which may be fixed or fluidized and may work by physical adsorption or irreversible chemisorption.

The point of use scrubber comprises a lower section plenum space, where process effluent waste stream containing an arsenic component is introduced; a sorbent bed section for contacting the arsenic containing component to react therewith to chemisorb of physisorb thereon the toxic arsenic component, to achieve a target abatement performance for the arsenic containing component; and an upper section plenum space where treated effluent passes prior to exiting the scrubber for disposition to a main abatement system or other disposition steps.

By trapping the arsenic containing components, particularly AsCl₃, close to the process chamber, rather than 20-30 feet downstream a significant cost saving for both installation and maintenance is realized because precipitation of toxic arsenic containing component in the downstream exhaust line is avoided and a safer work environment due to decreased risk for arsenic exposure created.

By pre-treating the arsenic containing waste stream effluent with the present invention scrubber system, high conductance in the downstream process line is maintained, because the arsine-containing component is removed from the process exhaust line, to below TLV, prior to it contacting water and/or air in the downstream process exhaust line.

Further, the present invention obviates the potential for arsenic containing precipitates to settle out in an exhaust line of a main scrubber unit coupled to duct work of a house exhaust system, because the arsine containing component is removed from the process exhaust line, before it could contact water and/or air present in the main scrubber's exhaust line or the house exhaust system duct work.

The present invention therefore, provides for the pre-treatment of an effluent waste stream having a toxic component deriving from a semiconductor etch process where the toxic component when exposed to air or water forms a precipitate that can settle out in the process lines downstream of a process pump and upstream of a main abatement system.

The canister employed in the point of use scrubber of the present invention may be manufactured in any shape or size useful for processing an effluent stream comprising a hazardous component. In a preferred embodiment, the canister is of a cylindrical or cubic geometry having a volume that is between 0.1 to 1000 liters, and more preferably between 4 and 50 liters.

The three main components of the interior section of the canister, mainly lower and upper plenum space and sorbent bed section, may occupy any percent of the canister's interior section. Further, multiple sorbent beds and multiple plenum spaces may be employed to more effectively scrub gaseous mixtures. Variables effecting the volume occupied by each of the three sections include but are not limited to process, volumes of toxic component to be abated, resin choice, effluent fluid flow, canister shape, inlet design etc.

A cubic container may be adapted to minimize volumetric space requirements in storage, transport and use. In one specific embodiment, the abatement apparatus includes a cubic up-flow canister having at least an upper and lower plenum space and a sorbent bed therebetween.

As used herein the terms “cube and “cubic” are interchangeable and are defined as having three dimensions and six faces, where the angle between any two adjacent faces is a right angle.

In a further embodiment the instant invention, relates to a point of use scrubber system for pre-treating an effluent waste stream comprising an arsenic component, said waste stream deriving from an upstream process pump of a compound semiconductor etch process tool, said pre-treat scrubber system comprising:

a compound semiconductor etch chamber for etch processing of a gallium arsenide substrate;

a process pump downstream of and coupled to said etch chamber for removing the effluent waste stream comprising arsenic component from said etch chamber;

a main abatement system downstream of said process pump for receiving and treatment of the effluent waste stream comprising arsenic component; and

a scrubber comprising a dry resin sorbent bed, located downstream of the process pump and upstream of said main abatement system, and in fluid flow communication with the arsenic containing effluent waste stream, such that the effluent waste stream contacts said dry resin sorbent bed prior to entry into said main abatement system, to reduce therein, the concentration of arsenic containing component in the effluent waste stream.

Preferably, the effluent waste stream flows through the scrubber container and sorbent bed in an up-flow direction from bottom to top. In one embodiment, sorbent beds are layered in the container and a plenum space may reside therebetween. The first layer may for example treat the arsenic-containing component, while the second layer may be specific to the BCl₃ component. The by-products formed upon reaction of the halogenated gases and the sorbent bed are nonvolatile inorganic compounds.

Arsenic chloride is a major by-product in gallium arsenide etch systems, which use, among others chlorine (Cl₂), and boron trichloride (BCl₃) etch gases. Arsenic chloride readily condenses in the downstream pump line and clogs vacuum exhaust lines and any entrance to a downstream scrubber. The arsenic containing condensables may be further compounded by solid boric oxide and boric acid, which readily form by the reaction of BCl₃ with water vapor and oxygen. When arsenic and/or boron containing oxides precipitate in the pump line, pumping speed is reduced resulting in process variability and yield loss.

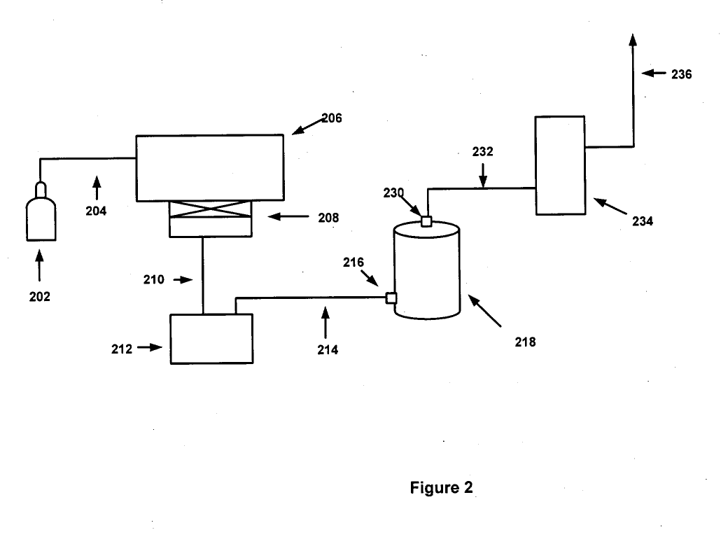

FIG. 2 shows a compound semiconductor process employing a point of use scrubber system for pre-treating an effluent waste stream as described hereinabove. Etching gas, such as BCl₃ flows from gas source cylinder 202, through process line 204 to etching chamber 206 employing high vacuum turbo pump 208. A wafer comprising a gallium arsenide substrate surface (not shown), resides in etching chamber 206. The substrate surface contacts BCl₃ etching gas and reacts therewith to form volatile GaCl₃ and AsCl₃. Effluent waste comprising GaCl₃, AsCl₃, unreacted etchant gas BCl₃, and byproducts thereof, are removed from the surface of the wafer and out of the etch chamber in process exhaust line 210, by high vacuum turbo pump 208 and the tool's exhaust pump 212, and flowed through pump exhaust line 214 to inlet 216 of pretreatment scrubber 218.

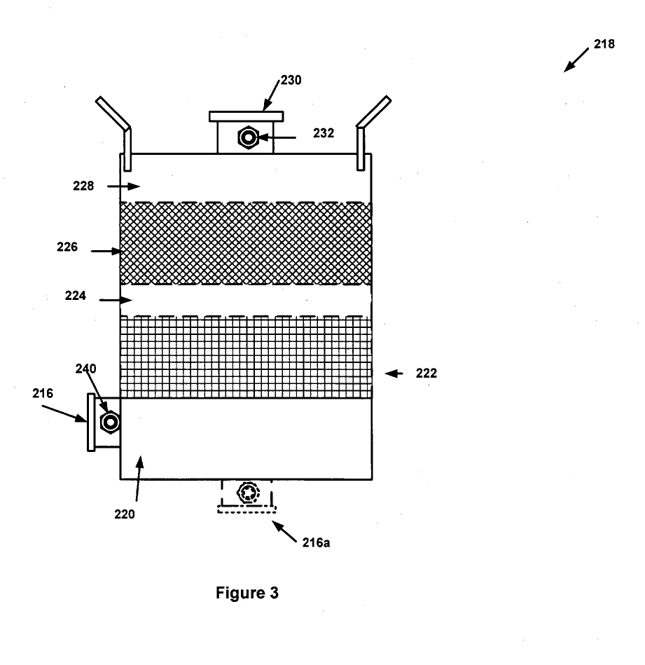

FIG. 3 shows a more detailed version of pretreatment scrubber 218, where effluent waste flows through inlet 216, (optionally 216a) into lower section plenum space 220, where the effluent stream mixes and expands, until the process effluent is mass transported into a first sorbent bed section 222, in an up-flow direction, by a pressure differential induced by a downstream fluid motive force driving device (not shown). In order to provide the plenum space, a support or supports may be inserted into the canister in order to support the sorbent bed and the sorbent bed material may be reposed on a mesh, screen or grid, with the bed being correspondingly confined at its upper end by a corresponding structure (not shown). Preferably effluent enters the canister at a cross-sectional center at a bed inlet (the cross-section being transverse to the flow direction of the gas stream being flowed through the bed for example 216a).

The arsenic containing toxic gas component contacts the sorbent material in first sorbent bed section 222, and the sorbent material, having an affinity for the arsenic gas component retains thereon and/or reacts therewith, by chemisorption or physisorption, in an evenly distributed manner the arsenic containing component, to create a uniform fluid front or mass transfer zone (MTZ), which theoretically transfers evenly through the first sorbent bed material. The effluent stream having a reduced concentration of arsenic component exits the first sorbent bed section 216 and flows into a center section plenum space 224 where it again, expands and mixes. The effluent stream having a reduced concentration of arsenic component contacts sorbent bed section 226, and the sorbent material having an affinity for the unreacted BCl₃ component retains thereon and/or reacts therewith, by chemisorption or physisorption, in an evenly distributed manner, the BCl₃ component, to create a uniform fluid front or mass transfer zone (MTZ), which theoretically transfers evenly through the first sorbent bed material. The effluent stream, now having a reduced concentration of both arsenic containing component and unreacted BCl₃ component, flows into the upper plenum section plenum space 228 where it again, expands before exiting pretreatment scrubber 218 through outlet port 230 where the effluent waste stream passes to an exhaust line for further disposition or for treatment by a downstream main abatement system.

Referring again to FIG. 2, where scrubber exhaust effluent waste stream line 232 the length of which may be up to 30 feet, exhausts the effluent waste stream now comprising a concentration of BCl₃ and AsCl₃ that is below TLV, to exhaust line 232, coupled to wet scrubber 234, for further decontamination treatment.

While the embodiment of the invention illustratively shown in FIG. 3 is provided with two layers of varying sorbent materials, it will be recognized that the invention may be practiced with a single bed or multiple beds of the sorbent material.

Various options are usefully employed with the scrubber system as described hereinabove including but not limited to end point monitoring, pressure and temperature sensing.

Referring again to FIG. 3, an end point monitor 240, such as a toxic gas sensor, may be coupled to an output module for outputting an indication of breakthrough of the contaminant(s) in the effluent gas stream when the capacity of the scrubber bed for active processing of the effluent gas stream is exhausted or reaches a predetermined approach to exhaustion (e.g., reaches a point of exhaustion of 95% of the total capacity of the dry scrubber material).

Optionally, a pressure sensing device 234, to monitor the pressure at the canister inlet, may be coupled to an output module for outputting an indication of pressure for increasing or decreasing the energy input on the downstream fluid motive force device or to signal a blockage in the sorbent bed or scrubber inlet.

A thermal monitoring device may be coupled to an output module for outputting an indication of temperature within the canister and sorbent bed(s). In this respect, a number of thermal monitoring devices, e.g., thermocouples, temperature probes, pyroelectric devices, etc., may be employed along the length of the bed in the direction of gas flow therethrough.

The present invention provides an abatement system and process for the pre-treatment of arsenic containing components as well as other toxic and/or hazardous component in an effluent waste stream, whereby the system provides for increased through-put in a semiconductor etch process, thereby reducing the tool mean time to maintenance.

Advantageously, the instant invention also provides an inexpensive solution to the potential release of toxic arsenic oxides to a semiconductor facility and/or environment. The inexpensive benefits of the system are in part due to the small footprint of the system and in further part due to the low maintenance required for such a system as there are no moving parts and only small amounts of toxic waste are generated for disposal. Additionally, there are no adverse conditions occurring at the etch process due to the operation of such a system.

The sorbent material used in the up-flow canister of the present invention may react with contaminants in an effluent waste stream (adsorbate) by physical or chemical adsorption kinetics. Physical adsorption is due to intermolecular forces between an adsorbent and adsorbate (e.g. van der Waals interactions) and thus is reversible. Chemical adsorption involves a chemical reaction between the adsorbent and the adsorbate. Preferably the up-flow canister of the present invention utilizes a dry scrubbing medium having a chemisorption relationship with process contaminants.

The system of the instant invention, preferably utilizes a dry resin sorbent material for trapping by chemisorption or physisorption reaction at least an arsenic containing component in an effluent waste stream line deriving from an exhaust pump of a semiconductor etch process. The dry resin sorbent material may comprise any combination of resins useful for scrubbing process gases specific to the particular process tool requiring effluent abatement and may be readily determined by those of skill in the art. Sorbent bed materials include but are not limited to: carbon, CuSO₄, Cu(OH₂), CuO, CuCO₃.CuCO₃.Cu(OH)₂, Cu₂O, MnOₓ, wherein x is from 1 to 2 inclusive, AgO, Ag₂O, CoO, Co₃O₄, Cr₂O₃, CrO₃, MoO₂, MoO₃, TiO₂, NiO, LiOH, Ca(OH)₂, CaO, NaOH, KOH, Fe₂O₃, ZnO, Al₂O₃, K₂CO₃, KHCO₃, Na₂CO₃, NaHCO₃, NH₃OH, Sr(OH)₂, HCOONa, BaOH, KMnO₄, SiO₂, ZnO, MgO, Mg(OH)₂, Na₂O₃S₂, SiO₂, triethylenediamine (TEDA) and mixtures thereof. Preferably, the dry resin sorbent material of the instant invention comprises at least one of Ca(OH)₂, CaO, CuSO₄, Cu(OH₂), CuO, CuCO₃, CuCO₃.Cu(OH)₂, Cu₂O Fe₂O₃.

Additionally, the sorbent material may further comprise a stabilizer or the active component may be impregnated into or coated onto an adsorbent substrate. Stabilizing materials help in the manufacturing of the sorbent media (e.g. in extrusion), and in some situations serves to prevent the sorbent media from decomposing. Useful stabilizers include but are not limited to the elements Be, Mg, transition metals selected from V, Mo, Co, Ni, Cu, Zn, B, Al, Si, Pb, Sb, Bi and oxides, hydroxides hydrogen carbonates, hydrogen sulfates, hydrogen phosphates, sulfides, peroxides, halides, carboxylates, and oxy acids thereof.

Accordingly, while the invention has been described herein with reference to specific features and illustrative embodiments, it will be recognized that the utility of the invention is not thus limited, but rather extends to and encompasses other features, modifications and alternative embodiments as will readily suggest themselves to those of ordinary skill in the art based on the disclosure and illustrative teachings herein. The claims that follow are therefore to be construed and interpreted as including all such features modifications and alternative embodiments within their spirit and scope.

I Claim:

1. A point of use scrubber for pre-treating an effluent waste stream comprising an arsenic component, said waste stream deriving from an upstream process pump of a compound semiconductor etch process, said scrubber comprising a canister having:
an inlet in gas flow communication with an upstream process exhaust pump;
an outlet in gas flow communication with a downstream, main abatement system; and
a sorbent bed;
wherein said sorbent bed contacts the effluent waste stream comprising the arsenic containing component ahead of the downstream main abatement system to effectively reduce the concentration of toxic arsenic component from the hazardous waste stream.

2. A point of use, scrubber for pre-treating an effluent waste stream comprising an arsenic component, said waste stream deriving from an upstream process pump of a compound semiconductor etch process, said scrubber comprising:
an up-flow canister comprising:
a lower section plenum space;
an upper section plenum space;
at least one dry resin sorbent bed layer therebetween
an inlet in gas flow communication with the upstream process pump; and
an outlet in gas flow communication with a downstream main scrubber system,
arranged such that process effluent waste stream flows in an upward direction to effectively reduce the concentration of toxic arsenic component from the hazardous waste stream.

3. A process for reducing the concentration of arsenic containing component in an effluent waste stream deriving from an upstream process pump of a compound semiconductor etch process tool, said process comprising:
contacting the arsenic-containing component in the effluent waste stream with a dry resin sorbent material to effectively chemisorb or physisorb thereon at least a portion of the arsenic component,
wherein the scrubber system is coupled to the exhaust line of the process pump, upstream of a main abatement system.

4. A point of use scrubber system for pre-treating an effluent waste stream comprising an arsenic component, said waste stream deriving from an upstream process pump of a compound semiconductor etch process tool, said pre-treat scrubber system comprising:
a compound semiconductor etch chamber for etch processing of a gallium arsenide substrate;
a process pump downstream of and coupled to said etch chamber for removing the effluent waste stream comprising arsenic component from said etch chamber;
a main abatement system downstream of said process pump for receiving and treating of the effluent waste stream comprising arsenic component; and
a scrubber comprising a sorbent bed, located downstream of the process pump and upstream of said main abatement system, and in fluid flow communication with the arsenic containing effluent waste stream, such that the effluent waste stream contacts said sorbent bed prior to entry into said main abatement system, to reduce therein, the concentration of arsenic containing component in the effluent waste stream.

5. A process for the point of use scrubbing of an arsenic containing component in an effluent waste stream deriving from a compound semiconductor etch process tool, said process comprising:
contacting a gallium arsenide substrate disposed in an etch chamber, with a halogenated etching gas to produce a volatile etch by-product comprising arsenic;
withdrawing the effluent waste stream comprising the volatile etch by-product from the etch chamber, using a vacuum exhaust pump downstream of the etch chamber;
contacting the volatile etch by-product comprising arsenic with a dry resin sorbent material to effectively chemisorb or physisorb thereon at least a portion of the arsenic of the volatile etch by-product, thereby producing an effluent waste stream having a reduced concentration of arsenic; and
withdrawing from the dry resin sorbent material an effluent waste stream having a reduced concentration of arsenic for disposition to a main abatement system.
